(19) United States
(12) Patent Application Publication
(10) Pub. No.: US 2023/0411578 A1
(43) Pub. Date: Dec. 21, 2023

(54) MICRO-ELECTRONIC COMPONENT, BONDING BACKPLATE AND BONDING ASSEMBLY

(71) Applicant: Xiamen Extremely PQ Display Technology Co., Ltd., Xiamen (CN)

(72) Inventor: Gang MA, XIAMEN (CN)

(21) Appl. No.: 18/114,939

(22) Filed: Feb. 27, 2023

Related U.S. Application Data
(63) Continuation of application No. PCT/CN2022/099293, filed on Jun. 17, 2022.

(51) Int. Cl. H01L 33/62

(52) U.S. Cl. CPC H01L 33/62; H01L 2933/0066

(57) ABSTRACT

A micro-electronic component, a bonding backplate and a bonding assembly are provided. The micro-electronic component includes: a micro-electronic element; a first bonding pad disposed on the micro-electronic element; a first solder layer disposed on a side of the first bonding pad facing away from the micro-electronic element; and a second bonding pad disposed on a side of the first solder layer facing away from the first bonding pad. The micro-electronic component, the bonding backplate and the bonding assembly can achieve a secondary welding bonding at a bonded position in the welding bonding process of the electronic component.

### TECHNICAL FIELD

The disclosure relates to the field of electronic device technologies, and in particular to a micro-electronic component, a bonding backplate and a bonding assembly.

### BACKGROUND

Micro Light Emitting Diode (Micro LED) display technology is currently widely used in various display devices. Micro LED display backplate requires transferring and bonding a large number of Micro LED chips. The key to achieve mass production of the Micro LED display backplate is repairable technology after the bonding. In the related art, Micro LED chips are bonded by metal bonding technology, which is realized by heating and melting alloy with low melting point as the solder to form a metallurgical joint. Due to the gap between the Micro LED chips in the Micro LED display backplate is very small, if there is a defect in the transferring process or in the chips after the first bonding, it is necessary to repair and remove the chips at the defective position. During removing the defective chips, solder on solder pad layer of the backplate may be lost, transferred, or oxidized, resulting in welding failure. However, it is very difficult to generate a solder metal layer at a certain position of the welded backplate. Therefore, it is difficult to realize a secondary welding bonding at the bonded position of the Micro LED display backplate in the related art.

Therefore, it is urgent to provide a new technical solution to solve the problem of secondary welding bonding at the bonded position of the Micro LED display backplate.

### SUMMARY

Therefore, in order to overcome at least some of the defects in the related art, embodiments of the disclosure provide a micro-electronic component, a bonding backplate and a bonding assembly, which can achieve a secondary welding bonding at a bonded position in the welding bonding process of electronic components.

In a first aspect, an embodiment of the disclosure provides a micro-electronic component, including: a micro-electronic element, a first bonding pad disposed on the micro-electronic element, a first solder layer disposed on a side of the first bonding pad facing away from the micro-electronic element, and a second bonding pad disposed on a side of the first solder layer facing away from the first bonding pad.

The micro-electronic component provided by the above-described embodiment of the disclosure can be bonded on the side of the second bonding pad facing away from the first solder layer during the bonding welding process, which is realized by setting two bonding pads and setting the first solder layer between the two bonding pads. If there is a defect in the bonding, it is necessary to repair, so that the first solder layer is used for the secondary welding bonding, which is achieved without generating a solder metal layer at the bonded position of the overall welded backplate.

In an embodiment, the micro-electronic component further includes: a second solder layer, which is disposed on a side of the second bonding pad facing away from the first solder layer.

In an embodiment, a melting point of the second solder layer is lower than that of the first solder layer.

In an embodiment, the first solder layer includes: a first metal layer and a second metal layer, the first metal layer and the second metal layer are capable of alloying to form a first alloy layer, a melting point of each of the first metal layer and the second metal layer is greater than a melting point of the second solder layer, and a melting point of the first alloy layer is lower than that of the second solder layer.

In an embodiment, the first bonding pad includes: a first adhesive layer and a first solder pad layer, and the first adhesive layer is disposed between the first solder pad layer and the micro-electronic element; the second bonding pad includes: a second adhesive layer and a second solder pad layer, and the second adhesive layer is disposed between the first solder layer and the second solder pad layer.

In an embodiment, the micro-electronic element includes a chip electrode on a surface of the micro-electronic element, the first bonding pad connects to the chip electrode and an area of orthographic projection of the first bonding pad on the surface of the micro-electronic element is 1.15-2.5 times of an area of orthographic projection of the chip electrode on the surface of the micro-electronic element.

In an embodiment, an area of orthographic projection of the first bonding pad on the surface of the micro-electronic element is 1.15-2.5 times of an area of orthographic projection of the first solder layer on the surface of the micro-electronic element.

In a second aspect, an embodiment of the disclosure provides a bonding backplate, including: a substrate, a first bonding pad disposed on a side of the substrate, a first solder layer disposed on a side of the first bonding pad facing away from the substrate, and a second bonding pad disposed on a side of the first solder layer facing away from the first bonding pad.

When the micro-electronic element is bonded to the bonding backplate, the bonding backplate provided by the above-described embodiment of the disclosure firstly bonds the micro-electronic element to the side of the second bonding pad facing away from the first solder layer, which is realized by setting the two bonding pads on the substrate and setting the first solder layer between the two bonding pads. If there is a defect in the bonding, it needs to repair, so that the original micro-electronic element can be removed and a new micro-electronic element can be bonded through the first solder layer. Therefore, there is no need to generate a solder metal layer at the bonded position of the overall welded backplate to achieve the secondary welding bonding.

In an embodiment, the first solder layer includes: a first metal layer and a second metal layer, and the first metal layer and the second metal layer are capable of alloying to form a first alloy layer.

In an embodiment, the bonding backplate further includes: a second solder layer, which is disposed on a side of the second bonding pad facing away from the first solder layer.

In an embodiment, the substrate includes a substrate electrode on a surface of the substrate, and an area of orthographic projection of the first bonding pad on the surface of the substrate is 1.15-2.5 times of an area of orthographic projection of the substrate electrode on the surface of the substrate.

In an embodiment, an area of orthographic projection of the first bonding pad on the surface of the substrate is 1.15-2.5 times of an area of orthographic projection of the first solder layer on the surface of the substrate.

In a third aspect, an embodiment of the disclosure provides a bonding assembly, including a micro-electronic element and a substrate configured to bond the micro-electronic element. The substrate is provided with a first bonding pad, and the micro-electronic element is provided with a second bonding pad corresponding to the first bonding pad. In addition, the bonding assembly further includes: a first solder layer, which is disposed between the first bonding pad and the second bonding pad, and a second solder layer, which is disposed between the first solder layer and the second bonding pad. A melting point of the second solder layer is different from that of the first solder layer. The first solder layer and the second solder layer are both fixed on one of the first bonding pad and the second bonding pad; in another way; or one of the first solder layer and the second solder layer is fixed on the first bonding pad, and the other is fixed on the second bonding pad.

When the micro-electronic element is firstly bonded to the substrate, the bonding assembly provided by the above-described embodiment of the disclosure can control the temperature by setting the two solder layers with different melting points, which only needs to melt one of the two solder layers to realize the welding. When the bonding defect appears, which needs to be repaired, the micro-electronic element can be removed and another solder layer can be used for a secondary bonding, so that the secondary welding bonding can be achieved without the need to generate the solder metal layer at the bonded position of the overall welded backplate.

In an embodiment, the first solder layer and the second solder layer are fixed on the first bonding pad, and the melting point of the first solder layer is higher than that of the second solder layer.

In an embodiment, the first solder layer and the second solder layer are fixed on the second bonding pad, and the melting point of the second solder layer is higher than that of the first solder layer.

In an embodiment, the bonding assembly further includes: a third bonding pad, which is disposed between the first solder layer and the second solder layer.

In an embodiment, the first solder layer is fixed on the first bonding pad, the third bonding pad is fixed on the first solder layer, and the melting point of the first solder layer is higher than that of the second solder layer.

In an embodiment, the second solder layer is fixed on the second bonding pad, the third bonding pad is fixed on the second solder layer, and the melting point of the second solder layer is higher than that of the first solder layer.

In an embodiment, the first solder layer is fixed on the first bonding pad, the third bonding pad is fixed on the first solder layer, and the first solder layer includes: a first metal layer and a second metal layer, the first metal layer and the second metal layer are capable of alloying to form a first alloy layer. Or in another way, the second solder layer is fixed on the second bonding pad, the third bonding pad is fixed on the second solder layer, and the second solder layer includes: a third metal layer and a fourth metal layer, the third metal layer and the fourth metal layer are capable of alloying to form a second alloy layer.

In an embodiment, the substrate includes a substrate electrode on a surface of the substrate, the first bonding pad connects to the substrate electrode, and an area of orthographic projection of the first bonding pad on the surface of the substrate is 1.15-2.5 times of an area of orthographic projection of the substrate electrode on the surface of the substrate; and/or the micro-electronic element includes a chip electrode on a surface of the micro-electronic element, the second bonding pad connects to the chip electrode, and an area of orthographic projection of the second bonding pad on the surface of the micro-electronic element is 1.15-2.5 times of an area of orthographic projection of the chip electrode on the surface of the micro-electronic element.

It can be seen from the above that the above embodiments of the disclosure can achieve one or more of the following beneficial effects. By adopting a solder layer between two bonding pads on the micro-electronic element or on the bonding back plane, or making the solder layer with two layers of different melting points, solder self-replenishment can be achieved, thereby to realize the secondary welding bonding at the bonded position without the need to generate the solder metal layer at the position of the overall welded backplane.

Through the following detailed description with reference to the attached drawings, other aspects and features of the disclosure become obvious. However, it should be understood that the drawings are only designed for the purpose of explanation, not as a limitation of the scope of the disclosure. It should also be understood that, unless otherwise noted, it is not necessary to draw the drawings to scale, and the drawings only attempt to conceptually illustrate the structure and process described herein.

### BRIEF DESCRIPTION OF THE DRAWINGS

Embodiments of the disclosure will be described in detail below in combination with the attached drawings.

FIG. 1A illustrates a schematic structural diagram of a micro-electronic component according to a first embodiment of the disclosure.

FIG. 1B illustrates a schematic structural diagram of another micro-electronic component according to the first embodiment of the disclosure.

FIG. 1C illustrates a schematic structural diagram of still another micro-electronic component according to the first embodiment of the disclosure.

FIG. 2 illustrates a schematic structural diagram of another micro-electronic component according to the first embodiment of the disclosure.

FIG. 3A illustrates a schematic structural diagram of an illustrated implementation of the micro-electronic component shown in FIG. 1A.

FIG. 3B illustrates a schematic structural diagram of an illustrated implementation of the micro-electronic component shown in FIG. 3A.

FIG. 4 illustrates a schematic structural diagram of another illustrated implementation of the micro-electronic component shown in FIG. 1A.

FIG. 5 illustrates a schematic diagram of a process of bonding the micro-electronic component shown in FIG. 4 to a bonding backplate.

FIG. 6 illustrates a schematic diagram of a repairing process of a structure after the process shown in FIG. 5 according to an embodiment of the disclosure.

FIG. 7 illustrates a schematic diagram of a repairing process of a structure after the process shown in FIG. 5 according to another embodiment of the disclosure.

FIG. 8A illustrates a schematic structural diagram of a bonding backplate according to a second embodiment of the disclosure.

FIG. 8B illustrates a schematic structural diagram of another bonding backplate according to the second embodiment of the disclosure.

FIG. 8C illustrates a schematic structural diagram of still another bonding backplate according to the second embodiment of the disclosure.

FIG. 9A illustrates a schematic structural diagram of an illustrated implementation of the bonding backplate shown in FIG. 8A.

FIG. 9B illustrates a schematic structural diagram of an illustrated implementation of the bonding backplate shown in FIG. 8A.

FIG. 10 illustrates a schematic structural diagram of another illustrated implementation of the bonding backplate shown in FIG. 8A.

FIG. 11 illustrates a schematic diagram of a bonding process of the bonding backplate shown in FIG. 10 and the micro-electronic element according to an embodiment of the disclosure.

FIG. 12 illustrates a schematic diagram of a repairing process of a structure after the bonding process shown in FIG. 11 according to an embodiment of the disclosure.

FIG. 13A illustrates a schematic structural diagram of a bonding assembly according to a third embodiment of the disclosure.

FIG. 13B illustrates a schematic structural diagram of an illustrated implementation of the bonding assembly shown in FIG. 13A.

FIG. 13C illustrates a schematic structural diagram of another illustrated implementation of the bonding assembly shown in FIG. 13A.

FIG. 14 illustrates a schematic structural diagram of another bonding assembly according to the third embodiment of the disclosure.

FIG. 15 illustrates a schematic structural diagram of still another bonding assembly according to the third embodiment of the disclosure.

### DESCRIPTION OF REFERENCE NUMERALS

10: micro-electronic component; 11: micro-electronic element; 111: chip electrode; 12, 14: bonding pad; 13, 15: solder layer; 121, 141: adhesive layer; 122, 142: solder pad layer; 131, 132: mental layer; 133: alloy layer;
20: bonding backplate; 21: substrate; 211: substrate electrode; 22, 24: bonding pad; 23, 25: solder layer; 221, 241: adhesive layer; 222, 242: solder pad layer; 231, 232: mental layer; 233: alloy layer;
30: bonding assembly; 31: micro-electronic element; 311: chip electrode; 32: substrate; 321: substrate electrode; 33, 34, 37: bonding pad; 35, 36: solder layer; 331, 341, 371: adhesive layer; 332, 342, 372: solder pad layer; 351, 352, 361, 362: mental layer.

### DETAILED DESCRIPTION OF THE EMBODIMENTS

In order to make the above purpose, features and advantages of the disclosure more obvious and easier to understand, the embodiments of the disclosure are described in detail below in combination with the attached drawings.

In order to enable those skilled in the art better understand the technical solutions of the disclosure, the technical solutions in the embodiments of the disclosure will be clearly and completely described below, with reference to the accompanying drawings in the embodiments of the disclosure. Apparently, the described embodiments are merely some of the embodiments of the disclosure, not all embodiments. Based on the described embodiments of the disclosure, all the other embodiments obtained by those skilled in the art without any creativity should belong to the scope of protection of the disclosure.

It should be noted that the terms “first” and “second” in the description and claims of the disclosure and the above described drawings are used to distinguish similar objects, and do not have to be used to describe a specific order or sequence. It should be understood that the terms so used are interchangeable under appropriate circumstances so that the embodiments of the disclosure described herein can be implemented in an order other than those illustrated or described herein. In addition, the terms “including” and “having” and any variations thereof are intended to cover non-exclusive inclusions, for example, processes, methods, systems, products or devices that contain a series of steps or units need not be limited to those clearly listed those steps or units, but may include other steps or units not explicitly listed or inherent to these processes, methods, products or equipment.

It should also be noted that the division of multiple embodiments in the disclosure is only for the convenience of description and should not constitute special restrictions. The features in various embodiments can be combined and quoted from each other without contradiction.

### First Embodiment

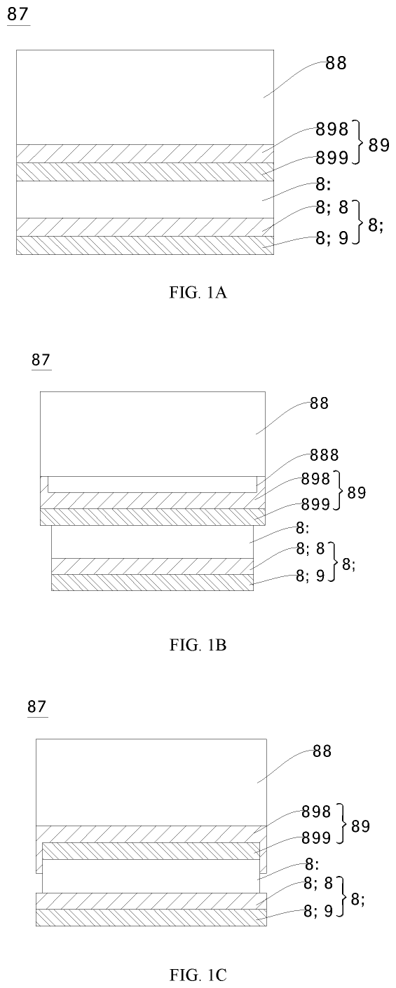

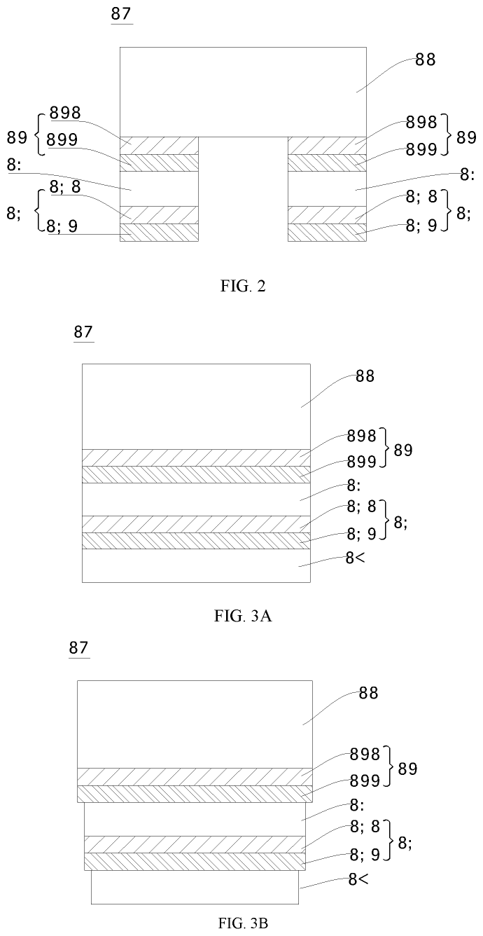

As shown in FIG. 1A, the first embodiment of the disclosure provides a micro-electronic component 10, including a micro-electronic element 11, a bonding pad 12, a solder layer 13 and a bonding pad 14. The bonding pad 12 is disposed on a side of the micro-electronic element 11, the solder layer 13 is disposed on a side of the bonding pad 12 facing away from the micro-electronic element 11, and the bonding pad 14 is disposed on a side of the solder layer 13 facing away from the bonding pad 12. The micro-electronic element 11 can be a micro light emitting element, especially, a micro light emitting diode (Micro LED) chip is taken as the example, which has an N-type semiconductor layer and a P-type semiconductor layer. Specially, in an illustrated embodiment, as shown in FIG. 1A, when the micro-electronic element 11 is a vertical Micro LED, the bonding pad 12, the solder layer 13 and the bonding pad 14 are disposed on the P-type semiconductor layer of the Micro LED to form a one-column stacked structure on the side of the micro-electronic element 11. In another illustrated embodiment, as shown in FIG. 2, when the micro-electronic element 11 is an flip-chip Micro LED chip, the P-type semiconductor layer and the N-type semiconductor layer are respectively provided with the bonding pad 12, the solder layer 13 and the bonding pad 14 to form a two-column stacked structure on the side of the micro-electronic element 11. Referring to FIG. 1A, the bonding pad 12 includes: an adhesive layer 121 and a solder pad layer 122, and the adhesive layer 121 is disposed between the solder pad layer 122 and the micro-electronic element 11. The bonding pad 14 includes: an adhesive layer 141 and a solder pad layer 142, and the adhesive layer 141 is disposed between the solder pad layer 142 and the solder layer 13. The adhesive layer 121 and the adhesive layer 141 can be, for example, chromium (Cr) metal layer or titanium (Ti) metal layer, and the solder pad layer 122 and the solder pad 142 can be, for example, copper (Cu) metal layer or nickel (Ni) metal layer. The bonding pad 12 and the bonding pad 14 can be combined with solder to realize the welding bonding. In an illustrated embodiment of the disclosure, the solder pad layer 122 and the solder pad layer 142 are used to realize the combination with the solder, however, the adhesive layer 121 is used to isolate the solder pad layer 122 and the micro-electronic element 11, and the adhesive layer 141 is used to isolate the solder pad layer 142 and the solder layer 13. The solder layer 13 can be made of solder alloy with low melting point, for example, tin bismuth alloy, etc., and the solder layer 13 is heated to connect to soldered objects. The bonding pad 12, the solder layer 13 and the bonding pad 14 can be deposited on the micro-electronic element 11 by low-temperature deposition methods such as low-temperature magnetron sputtering. The low-temperature deposition method ensures that the solder layer 13 will not melt during the deposition process. Thicknesses of the adhesive layer 121, the adhesive layer 141, the solder pad layer 122 and the solder pad layer 142 are approximately 0.2 micrometer (μm) to 1 μm. A thickness of the solder layer 13 is approximately 2 μm to 4 μm.

In an illustrated embodiment, the micro-electronic element 11 includes a chip electrode 111 on a surface of the micro-electronic element. The Micro LED chip is taken as an example, the chip electrode 111 includes a positive (P) electrode and a negative (N) electrode, and the bonding pad 12 connects to the chip electrode 111. In some embodiments, an area of orthographic projection S1 of the chip electrode 111 on a surface of the micro-electronic element 11 is different from an area of orthographic projection S2 of the bonding pad 12 on the surface of the micro-electronic element 11. In an illustrated embodiment, S2 is greater than S1 and more specifically, S2 is 1.15-2.5 times of S1, which can more effectively separate the chip electrode 111 from the solder layer 13 and play a better solder resistance effect. Furthermore, an area of orthographic projection S21 of the adhesive layer 121 on the surface of the micro-electronic element 11 is greater than S1 and S21 is 1.15-2.5 times of S1. Referring to FIG. 1B, the adhesive layer 121 also extends to a side of the chip electrode 111 facing toward a side close to the surface of the micro-electronic element 11 to better obstruct the chip electrode 111. An area of orthographic projection S22 of the solder pad layer 122 on the surface of the micro-electronic element 11 can be less than S21.

Referring to FIG. 1B, in some embodiments, an area of orthographic projection S3 of the solder layer 13 on the surface of the micro-electronic element 11 is different from S2. In an illustrated embodiment, S2 is greater than S3 and more specially, S2 is 1.15-2.5 times of S3. Therefore, it is possible to prevent an overflow of the solder layer 13 during its melting to be welded, provide a larger welding area, and play a better welding assistance. In an illustrated embodiment, the area of orthographic projection S21 of the adhesive layer 121 on the surface of the micro-electronic element 11 is greater than S3, and S21 is 1.15-2.5 times of S3. As shown in FIG. 1C, in some embodiments, the adhesive layer 121 also extends to a side of the solder layer 13 facing toward a side close to the solder layer 13. It can be understood that the adhesive layer 121 forms a groove thereon, and the solder layer 13 is disposed in the groove to better prevent the overflow of the solder layer 13. In the embodiment, a size relationship between S1 and S3 is not limited, nor is a size relationship between the bonding pad 12 and the bonding pad 14.

In an illustrated embodiment of the disclosure, the Micro LED chip is taken as the micro-electronic element 11. The Micro LED chips usually need to be transferred and bonded to a drive circuit substrate in batches to form a Micro LED display backplate, while the gap between the transferred Micro LED chips is small, generally lower than 100 Therefore, when the metal welding bonding is adopted, if there is a defect after the first bonding, it is necessary to repair at the bonded position where the defect exists. Firstly, the Micro LED chip in the first bonding need to be removed, and then a new Micro LED chip is transferred to the defective position for a secondary bonding. However, it is difficult to generate solder at a certain single position of the drive circuit substrate that has been welded as a whole. The micro-electronic component 10 provided by the first embodiment can achieve two times of bonding. During the first bonding process, a layer of solder layer can be pre-fabricated on a side of the bonding pad 14 of each of the multiple micro-electronic components 10 facing away from the solder layer 13, or in another way, a layer of solder layer can be pre-fabricated at the corresponding bonding position on the drive circuit substrate, and then the layer of solder layer is heated to achieve the bonding between the bonding pad 14 and the drive circuit substrate. In an illustrated embodiment of the disclosure, the heating temperature in the first bonding can be controlled so that the solder layer 13 does not melt. If there is a defect in the first bonding, it is necessary to remove the Micro LED chip that is bonded to the drive circuit substrate in the first bonding and it also needs to be repaired after the removal, which is regarded as a secondary bonding. In an illustrated embodiment of the disclosure, the Micro LED chip with great value can be removed from the side of the bonding pad 14 facing away from the solder layer 13 during the repairing process. The removed parts also include the Micro LED chip (also referred to the micro-electronic element 11), the bonding pad 12, the solder layer 13 and the bonding pad 14. At this time, the bonding pad 14 may have some loss. Then, the bonding pad 14 on the removed part is removed by plasma bombardment to expose the solder layer 13, so that the solder layer 13 can be bonded to the drive circuit substrate by heating the solder layer 13. In another way, the Micro LED chip can be removed from the side of the bonding pad 12 facing away from the solder layer 13, so that the bonding pad 12, the solder layer 13 and the bonding pad 14 are left on the drive circuit substrate, and then the bonding pad 12 left on the drive circuit substrate is removed to expose the solder layer 13, so that the bonding pad 14 and the new Micro LED chip are bonded, which is realized by heating the solder layer 13. The above description is only explained by referring to the micro-electronic element 11 being the Micro LED chip. In some embodiments of the disclosure, the micro-electronic element 11 can also be other micro-electronic elements with the same problem of secondary bonding welding of Micro LED. The first embodiment does not limit the types of the micro-electronic element 11.

FIG. 3A illustrates a schematic structural diagram of an implementation of the micro-electronic component 10 shown in FIG. 1A. As shown in FIG. 3A, the micro-electronic component 10 further includes a solder layer 15, which is disposed a side of the bonding pad 14 facing away from the solder layer 13. By setting the solder layer 15, there is no need to make the layer of solder layer on the Micro LED drive circuit substrate. During the first bonding, the solder layer 15 is heated to melt to realize the first bonding. During the secondary bonding, the solder layer 13 is heated to achieve the secondary bonding. The solder layer 15 and the solder layer 13 are both alloy materials, and a melting point of the solder layer 15 is lower than that of the solder layer 13. Therefore, during the first bonding, only the solder layer 15 can be melted and the solder layer 13 cannot be melted. In an illustrated embodiment of the disclosure, the solder layer 15 is an alloy with a melting point of 145 Celsius degrees (° C.), the solder layer 13 is an alloy with a melting point of 221° C., and the heating temperature in the first bonding is 180° C., which melts the solder layer 15 and does not melt the solder layer 13. In an illustrated embodiment of the disclosure, the heating temperature in the secondary bonding is 250° C. to melt the solder layer 13. The technical solution provided by the above embodiment does not need to make the layer of solder layer at the certain single position on the integrally welded backplate, but only needs to heat the certain single position to melt the solder layer 13 to achieve the secondary welding bonding. Since the single-position heating is easier to achieve, and some heat dissipation measures are taken, which will not affect other points adjacent to the secondary welding position; therefore, the process difficulty is greatly reduced. In addition, since the bonding pad 14 is disposed between the solder layer 15 and the solder layer 13, it is not easy to cause loss of the solder layer 13 during the removal of the Micro LED chip before the secondary bonding process, so that in some embodiments, the melting point relationship between the solder layer 15 and the solder layer 13 can be unlimited.

In some embodiments, when the micro-electronic component 10 also includes the solder layer 15, an area of orthographic projection S4 of the bonding pad 14 on the surface of the micro-electronic element 11 is greater than an area of orthographic projection S5 of the solder layer 15 on the surface of the micro-electronic element 11. In an illustrated embodiment, S4 is 1.15-2.5 times of S5, which can prevent the overflow of the solder layer 15 during its melting to be welded and play a better welding assistance. In the illustrated embodiment, an area of orthographic projection S41 of the adhesive layer 141 on the micro-electronic element 11 is greater than S5 and more specially, S41 is 1.15-2.5 times of S5.

In some embodiments, the area of orthographic projection S2 of the bonding pad 12 on the surface of the micro-electronic element 11 is greater than the area of orthographic projection S5 of the solder layer 15 on the surface of the micro-electronic element 11, specially, S2 is 1.15-2.5 times of S5. In an illustrated embodiment, S21 is greater than S5 and S21 is 1.15-2.5 times of S5, which can better isolate the chip electrode 111 from the solder layer 15. But in the illustrated embodiment, a size relationship between S3 and S5 is not limited, nor is a size relationship between S2 and S4.

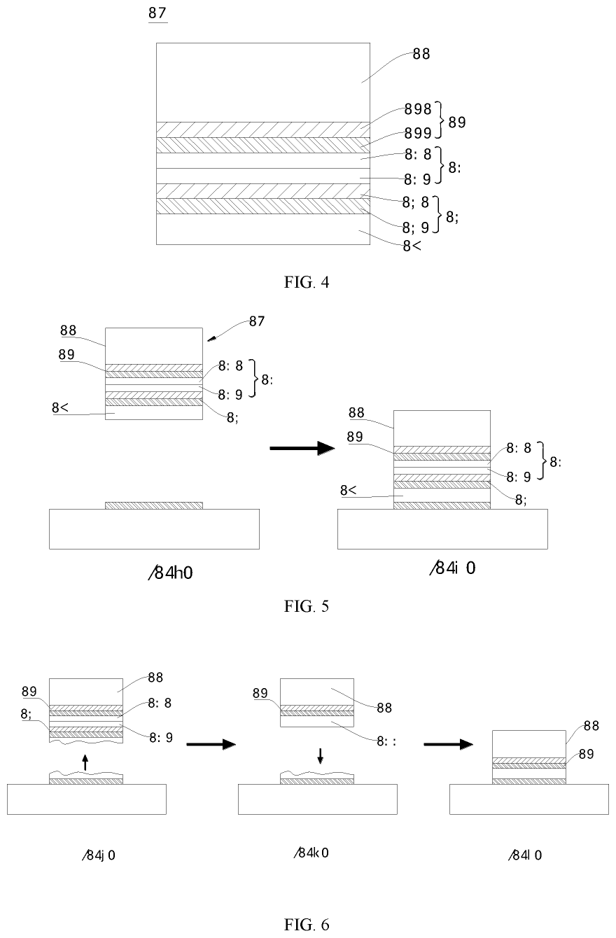

FIG. 4 illustrates a schematic structural diagram of another implementation of the micro-electronic component 10 shown in FIG. 1A. In the micro-electronic component 10 shown in FIG. 4, the solder layer 13 includes a metal layer 131 and a metal layer 132, which can be alloyed to form an alloy layer 133. In an illustrated embodiment of the disclosure, the solder layer 15 is made of alloy, a melting point of each of the metal layer 131 and the metal layer 132 is higher than that of the solder layer 15, and a melting point of the alloy layer 133 is lower than that of the solder layer 15. The metal layer 131 and the metal layer 132 are specifically pure metal layers. In an illustrated embodiment of the disclosure, the metal layer 131 and the metal layer 132 are respectively bismuth metal layer (melting point of 280° C.) and tin metal layer (melting point of 230° C.). After alloying the two pre-described mental layers, the bismuth-tin alloy layer (melting point of 145° C.) can be obtained. A relatively thin metal layer is included between the metal layer 131 and the metal layer 132 to assist in forming the alloy layer 133. In some embodiments, the solder layer 13 can include more layers of pure metal layers. The melting point of each layer of the pure metal layers is higher than that of the solder layer 15, and the melting point of the alloy layer 133 formed after alloying the multiple metal layers is lower than that of the solder layer 15. In an illustrated embodiment of the disclosure, if the solder layer 15 is an alloy with a melting point of 180° C., the melting point of the metal layer 131 is 280° C., the melting point of the metal layer 132 is 230° C., and the melting point of the alloy layer 133 is 145° C., and then the heating temperature is 190° C. to melt the solder layer 15 during the first bonding, while the metal layer 131 and the metal layer 132 do not melt. Before the secondary bonding, the solder layer 13 is firstly operated, namely, the metal layer 131 and the metal layer 132 are alloyed to form the alloy layer 133, so that the secondary bonding can be achieved by melting the alloy layer 133 at a lower temperature than 190° C. Therefore, the secondary bonding will not affect other positions adjacent to the bonded position during the repairing process.

In order to more clearly reflect how the micro-electronic component 10 provided in the first embodiment of the disclosure achieves the secondary welding bonding, the secondary bonding process of the first embodiment is described in detail in combination with FIGS. 5-7.

FIG. 5 illustrates a schematic diagram of a process of bonding the micro-electronic component 10 to a drive circuit substrate. In step (1-a), the micro-electronic component 10 and the drive circuit substrate are provided respectively, and the drive circuit substrate is provided with a bonding pad corresponding to the micro-electronic component 10. As shown in FIG. 5, the micro-electronic component 10 has a solder layer 15, so that a bonding structure shown in step (1-b) can be obtained by directly heating and melting the solder layer 15 to bond the micro-electronic element 11 to the drive circuit substrate. If the micro-electronic component 10 does not have the solder layer 15, a layer of solder layer is formed on the bonding pad of the drive circuit substrate first, and the layer of solder layer can be melted during the first bonding, and the bonding structure shown in step (1-b) can also be obtained.

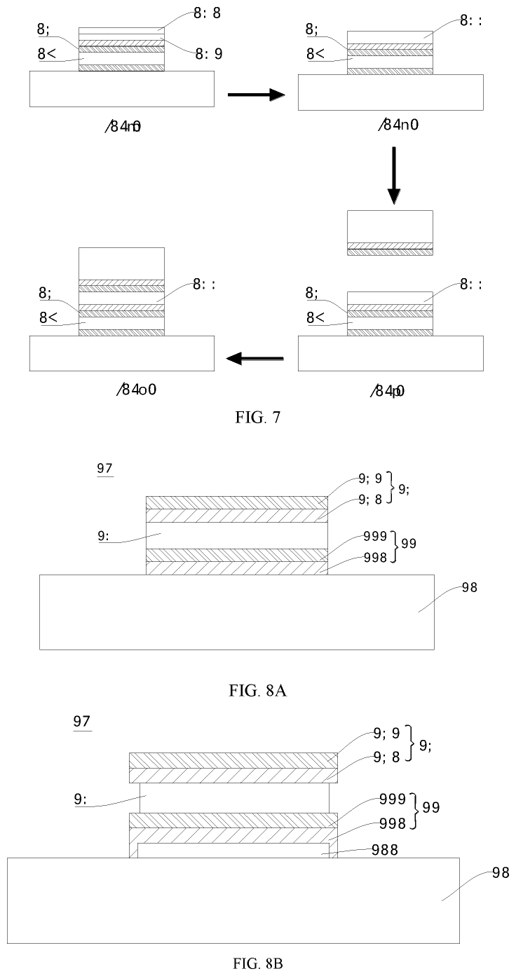

If there is a defect on a bonded position after the first bonding, it needs to be repaired, that is, the bonded position needs to be bonded again. For the bonding structure obtained in step (1-b) in FIG. 5, there are two ways to repair it. A first repairing method is shown in FIG. 6. In step (1-c), the micro-electronic component 10 is separated in the position the solder layer 15, that is, the micro-electronic component 10 excluding the solder layer 15 is removed from the drive circuit substrate (referred to as the original electronic component). The original electronic component includes the micro-electronic element 11, the bonding pad 12, the solder layer 13 and the bonding pad 14. At this time, the bonding pad 14 may have partial loss. In step (1-d), if the solder layer 13 containing the metal layer 131 and the metal layer 132 is adopted, the bonding pad 14 on the original electronic component shall be removed firstly to expose the solder layer 13, and then the metal layer 131 and the metal layer 132 are alloyed to make the solder layer 13 become the alloy layer 133, and finally the original electronic component is transferred to the bonded position again, and the alloy layer 133 is heated to melt to realize the secondary welding bonding, thereby to obtain a bonding structure in step (1-e). If the solder layer 13 is a common alloy layer, there is no need for alloying. After removing the bonding pad 14 on the original electronic component, the solder layer 13 can be directly heated to realize the secondary welding bonding. A second repairing method is shown in FIG. 7. In step (1-f), the micro-electronic element 11 of the micro-electronic component 10 is removed, so that the micro-electronic component 10 excluding the micro-electronic element 11 (referred to as the original welding structure) is remained on the drive circuit substrate. The original welding structure includes the solder layer 15, the bonding pad 14, the solder layer 13 and the bonding pad 12, and then the bonding pad 12 of the original welding structure is removed to expose the solder layer 13. In step (1-g), the metal layer 131 and the metal layer 132 are alloyed to form the alloy layer 133. In step (1-i), a new micro-electronic component 10 is transferred to the bonded position, and the solder layer of the new micro-electronic component 10 is bonded to the solder layer 13 of the original welding structure to complete bonding the new micro-electronic component 10 to the bonded position, thereby to complete the secondary bonding. In another way of the second repairing method, an ordinary Micro LED structure (only including a Micro LED chip and a bonding pad shown in step (1-i)) can also be transferred to the bonded position in the secondary bonding, and the solder layer 13 can be heated to complete the secondary bonding at the bonded position, thereby to obtain a bonding structure in step (1-h).

### Second Embodiment

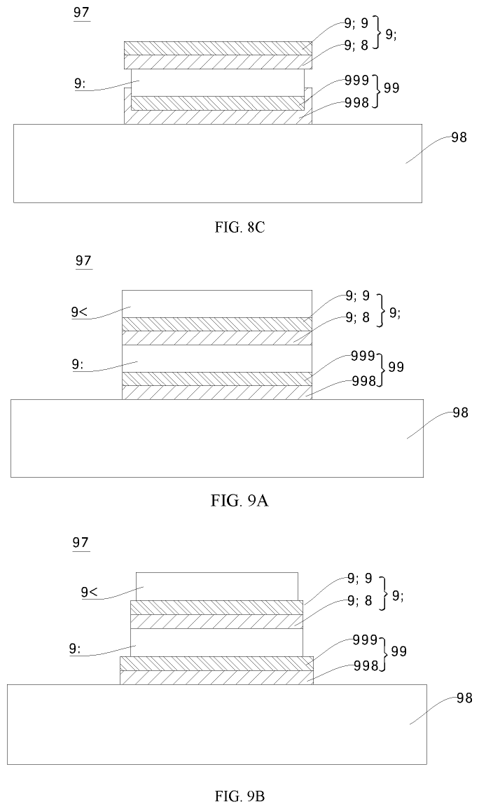

As shown in FIG. 8A, the second embodiment of the disclosure provides a bonding backplate 20, which includes a substrate 21, a bonding pad 22, a solder layer 23 and a bonding pad 24. The bonding pad 22 is disposed on a side of the substrate 21, the solder layer 23 is disposed on a side of the bonding pad 22 facing away from the substrate 21, and the bonding pad 24 is disposed on a side of the solder layer 23 facing away from the bonding pad 22. The Micro LED chips or other similar micro-electronic components are bonded to the bonding backplate 20, for example, the substrate 21 refers to a Micro LED drive circuit substrate, which includes a support base and a drive circuit layer disposed on the support base. The bonding pad 22 is disposed on the drive circuit layer and electrically connected to the drive circuit layer, so that when the Micro LED chip is bonded to the bonding backplate 20, it can realize the electrical connection between the Micro LED and the drive circuit layer, and drive the Micro LED to work through the drive circuit layer. It should be noted that FIG. 8A only illustrates there being one bonding pad 22 on the substrate 21, in the second embodiment, the substrate 21 is provided with multiple bonding pads 22. In an illustrated embodiment of the disclosure, when the bonding pads 22 are used to bond flip-chip Micro LED chips, each Micro LED chip has a P electrode (referred to a positive electrode) and a N electrode (referred to a negative electrode), so that two bonding pads 22 are disposed on the bonding position of the corresponding Micro LED, which correspond to the P electrode and the N electrode respectively. Therefore, the substrate 21 has n numbers of bonding positions corresponding to n numbers of Micro LEDs, namely that there are 2*n numbers of bonding pads 22. It can be understood that the number of the solder layer 23 corresponds to the number of the bonding pad 24 or the number of the bonding pad 22. In an illustrated embodiment of the disclosure, the bonding pad 22 includes an adhesive layer 221 and a solder pad layer 222, and the adhesive layer 221 is disposed between the solder pad layer 222 and the substrate 21; the bonding pad 24 includes an adhesive layer 241 and a solder pad layer 242, and the adhesive layer 241 is disposed between the solder pad layer 242 and the solder layer 23. The adhesive layer 221 and the adhesive layer 241 can be specifically Cr metal layer or Ti metal layer, etc., and the solder pad layer 222 and the solder pad layer 242 can be specifically Cu metal layer or Ni metal layer, etc. The bonding pad 22 and the bonding pad 24 are used to combine with solder to realize the bonding. The solder pad layer 222 and the solder pad layer 242 are mainly used to realize the combination with the solder, the adhesive layer 221 is mainly used to isolate the solder pad layer 222 and the substrate 21, and the adhesive layer 241 is mainly used to isolate the solder pad layer 242 and the solder layer 23. In an illustrated embodiment of the disclosure, the solder layer 23 can be made of solder alloy with low melting point, specially, tin bismuth alloy, etc. The solder layer 23 is heated to connect to the soldered objects. The bonding pad 22, the solder layer 23 and the bonding pad 24 can be deposited successively by low-temperature deposition methods such as the low-temperature magnetron sputtering. The low-temperature deposition process ensures that the solder layer 23 will not melt during the deposition process. Thicknesses of the adhesive layer 221, the adhesive layer 241, the solder pad layer 222 and the solder pad layer 242 are approximately 0.2 μm to 1 μm. A thickness of the solder layer 23 is approximately 2 μm to 4 μm.

In an illustrated embodiment, the substrate 21 includes a substrate electrode 211 on a surface of the substrate 21 and the bonding pad 22 connects to the substrate electrode 211. In some embodiments, an area of orthographic projection A1 of the substrate electrode 211 on the surface of the substrate 21 is different from an area of orthographic projection A2 of the bonding pad 22 on the surface of the substrate 21, specifically, A2 is greater than A1 and more specifically, A2 is 1.15-2.5 times of A1. The substrate electrode 211 can be more effectively separated from the solder layer 23 to achieve better solder resistance. In an illustrated embodiment, an area of orthographic projection A21 of the adhesive layer 221 on the surface of the substrate 21 is greater than A1, and more specifically, A21 is 1.15-2.5 times of A1. Referring to FIG. 8B, the adhesive layer 221 also extends to a side of the substrate electrode 211 facing toward a side close to the surface of the substrate 21 to better obstruct the substrate electrode 211. An area of orthographic projection A22 of the solder pad layer 222 on the surface of the substrate 21 can be less than A21.

Referring to FIG. 8B, in some embodiments, an area of orthographic projection A3 of the solder layer 23 on the surface of substrate 21 is different from A2. In an illustrated embodiment, A2 is greater than A3 and more specifically, A2 is 1.15-2.5 times of A3, which can prevent an overflow of the solder layer 23 during its melting to be welded, provide a larger welding area and play a better welding assistance. Furthermore, the area of orthographic projection A21 of the adhesive layer 221 on the surface of the substrate 21 is greater than A3 and more specifically, A21 is 1.15-2.5 times of A3. As shown in FIG. 8C, in some embodiments, the adhesive layer 221 also extends to a side of the solder layer 23 facing toward a side close to the solder layer 23. It can be understood that the adhesive layer 221 forms a groove thereon and the solder layer 23 is disposed in the groove to better prevent the overflow of the solder layer 23. In the embodiment, a size relationship between A1 and A3 is not shown, and a size relationship between the bonding pad 22 and the bonding pad 24 is not limited.

In an illustrated embodiment of the disclosure, the Micro LED chip is taken to bond to the bonding backplate 20 firstly. At this time, a layer of solder layer can be formed on the bonding pad 24 or on the Micro LED chip, so that the layer of solder layer is heated to bond to the bonding pad 24 and the Micro LED chip, thereby to bond the Micro LED chip to the substrate 21. After the first bonding, if there is a defect in the first bonding, the Micro LED chip in the first bonding needs to be removed, and the secondary bonding (also referred to the repairing process) should be carried out after the removal. During the secondary bonding, the Micro LED chip can be separated from the substrate 21 from the side of the bonding pad 24 facing away from the solder layer 23, leaving the bonding pad 22, the solder layer 23 and the bonding pad 24 on the substrate 21. At this time, the bonding pad 24 may be partially lost. In an illustrated embodiment of the disclosure, the bonding pad 24 is removed by plasma bombardment thereby to expose the solder layer 23, so that the solder layer 23 can be combined with the new Micro LED chip by heating the solder layer 23. The above description is only explained by taking the transferring of the Micro LED chip as an example. In some embodiments of the disclosure, the bonding backplate 20 can also be applied to the bonding of other micro-electronic components that also have the problem of secondary bonding welding of Micro LED. The embodiment does not limit the types of the bonding backplate 20.

FIG. 9A illustrates a schematic structural diagram of an implementation of the bonding backplate 20 shown in FIG. 8A. As shown in FIG. 9A, the bonding backplate 20 further includes a solder layer 25, which is disposed on a side of the bonding pad 24 facing away from the solder layer 23. By setting the solder layer 25, there is no need to make the layer of solder layer on the Micro LED chip in the first bonding. During the first bonding, the solder layer 25 is heated to achieve the first bonding. During the secondary bonding, the solder layer 23 is heated to achieve the secondary bonding process. The solder layer 25 and the solder layer 23 are both alloy materials, for example, and a melting point of the solder layer 25 is lower than that of the solder layer 23, then only the solder layer 25 can be melted and the solder layer 23 cannot be melted in the first bonding. In an illustrated embodiment of the disclosure, the solder layer 25 is an alloy with a melting point of 145° C., the solder layer 23 is an alloy with a melting point of 221° C., and the heating temperature in the first bonding is 180° C., which melts the solder layer 25 melt and does not melt the solder layer 23. The heating temperature in the secondary bonding, such as 250° C., melts the solder layer 23. Since the bonding pad 24 is disposed between the solder layer 25 and the solder layer 23, it is not easy to cause loss of the solder layer 23 during the removal before the secondary bonding, so that the melting point relationship between the solder layer 25 and the solder layer 23 can also be unlimited.

In some embodiments, when the bonding backplate 20 also includes the solder layer 25, an area of orthographic projection A4 of the bonding pad 24 on the surface of the substrate 21 is greater than an area of orthographic projection A5 of the solder layer 25 on the surface of the substrate 21. In an illustrated embodiment, A4 is 1.15-2.5 times of A5, which can prevent an overflow of the solder layer 25 during its melting to be welded and play a better welding assistance. In an illustrated embodiment, an area of orthographic projection A41 of the adhesive layer 242 on the surface of the substrate 21 is greater than A5, and more specifically, A41 is 1.15-2.5 times of A5.

In some embodiments, the area of orthographic projection A2 of the bonding pad 22 on the surface of the substrate 21 is greater than the area of orthographic projection A5 of the solder layer 25 on the surface of the substrate 21. In an illustrated embodiment, A2 is 1.15-2.5 times of A5, A21 is greater than A5 and A21 is 1.15-2.5 times of A5, which can better isolate the substrate electrode 211 from the solder layer 25. The embodiment does not limit a size relationship between A3 and A5, nor does it limit a size relationship between A2 and A4.

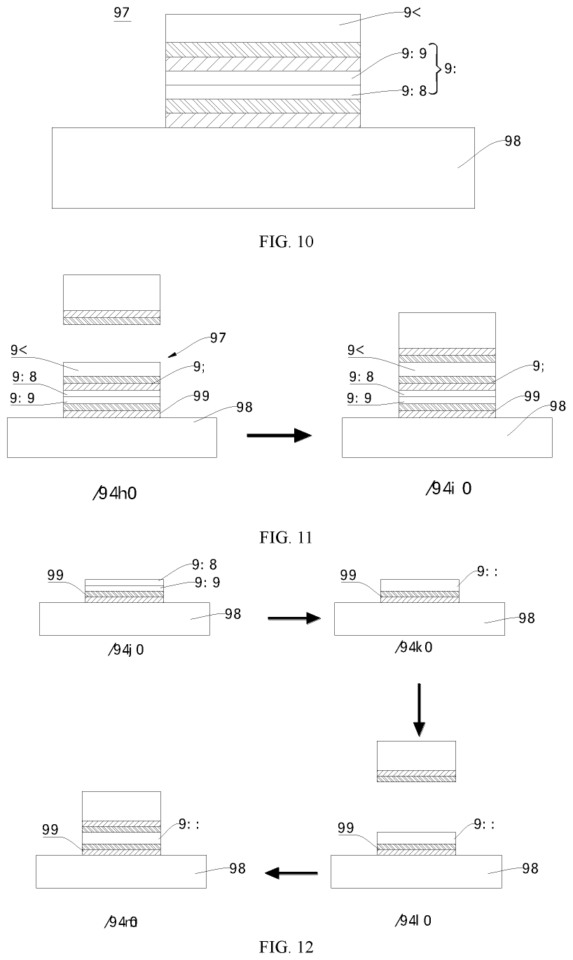

FIG. 10 illustrates a schematic structural diagram of another implementation of the bonding backplate 20 shown in FIG. 8A. In the bonding backplate 20 shown in FIG. 10, the solder layer 23 includes a metal layer 231 and a metal layer 232, the metal layer 231 and the metal layer 232 are capable of alloying to form an alloy layer 233. In an illustrated embodiment of the disclosure, the solder layer 25 is made of alloy materials, a melting point of each of the metal layer 231 and the metal layer 232 is higher than that of the solder layer 25, and a melting point of the alloy layer 233 is lower than that of the solder layer 25. The metal layer 231 and the metal layer 232 are specifically pure metal layers. In an illustrated embodiment of the disclosure, the metal layer 231 and the metal layer 232 are respectively bismuth metal layer (melting point of 280° C.) and tin metal layer (melting point of 230° C.). After alloying the two metal layers, the bismuth-tin alloy layer (melting point of 145° C.) is obtained. A relatively thin metal layer is disposed between the metal layer 231 and the metal layer 232 to assist in forming the alloy layer 233. In some embodiments, the solder layer 23 further includes multiple layers of pure metal layers. A melting point of each layer of the pure metal layers is higher than that of the solder layer 25. The melting point of the alloy layer formed after alloying the multiple layers of pure metal layers is lower than that of the solder layer 25. In an illustrated embodiment of the disclosure, the solder layer 25 is an alloy with a melting point of 180° C., the melting point of the metal layer 231 is 280° C., the melting point of the metal layer 232 is 230° C., and the melting point of the alloy layer 233 is 145° C. Therefore, the solder layer 25 melts when the heating temperature is 190° C. in the first bonding, while the metal layer 231 and the metal layer 232 do not melt. Before the secondary bonding, the solder layer 23 is firstly operated to alloy the metal layer 231 and the metal layer 232 to form the alloy layer 233, so that the secondary bonding is achieved by melting the alloy layer 233 at a lower temperature than 190° C. Therefore, the secondary bonding process will not affect other positions adjacent to the repair bonding position.

In order to more clearly reflect how the bonding backplate 20 provided in the second embodiment of the disclosure achieves the secondary welding bonding, the secondary bonding process of the second embodiment is described in detail in combination with FIGS. 11-12.

FIG. 11 illustrates a schematic diagram of the first bonding process of the bonding backplate on a certain bonding position. In step (2-a), the bonding backplate 20 and a micro-electronic element are provided respectively. In an illustrated embodiment of the disclosure, the micro-electronic element is provided with a bonding pad for connecting with the bonding backplate 20. As shown in FIG. 11, the bonding backplate 20 has a solder layer 25, so that a bonding structure in step (2-b) is obtained by directly heating and melting the solder layer 25 to bond the micro-electronic element to the bonding backplate 20. If there is no the solder layer 25 on the bonding backplate 20, a layer of solder layer is formed on the bonding pad of the micro-electronic element firstly, and the bonding structure in step (2-b) is also obtained by melting the layer of solder layer in the first bonding.

If there is a defect in the bonded position after the first bonding, it needs to be repaired, that is, it needs to generate a secondary bonding. For the bonding structure obtained in step (2-b), a repairing method is shown in FIG. 12. In step (2-c), the repairing method is to separate at the solder layer 25, namely, the micro-electronic element is removed from the bonding pad 24 (the removed micro-electronic element is not shown in FIG. 11), and the bonding pad 24 is removed at the bonded position to expose the solder layer 23. After step (2-c), only the bonding pad 22 and the solder layer 23 are left in the stacked structure at the bonded position of the substrate 21. In step (2-d), if the solder layer 23 includes the metal layer 231 and the metal layer 232, the metal layer 231 and the metal layer 232 are alloyed to make the solder layer 23 become the alloy layer 233. Finally, in step (2-e), a new micro-electronic element is provided to transfer to the solder layer 23 (i.e., the alloy layer 233), and the alloy layer 233 is heated to melt, thereby to realize the secondary bonding to obtain a bonding structure in step (2-f). Meanwhile, in an illustrated embodiment of the disclosure, the micro-electronic component 10 provided in the first embodiment of the disclosure can also be bonded to the bonding backplate 20 in the secondary bonding, thereby to provide the feasibility of multiple times of bonding.

### Third Embodiment

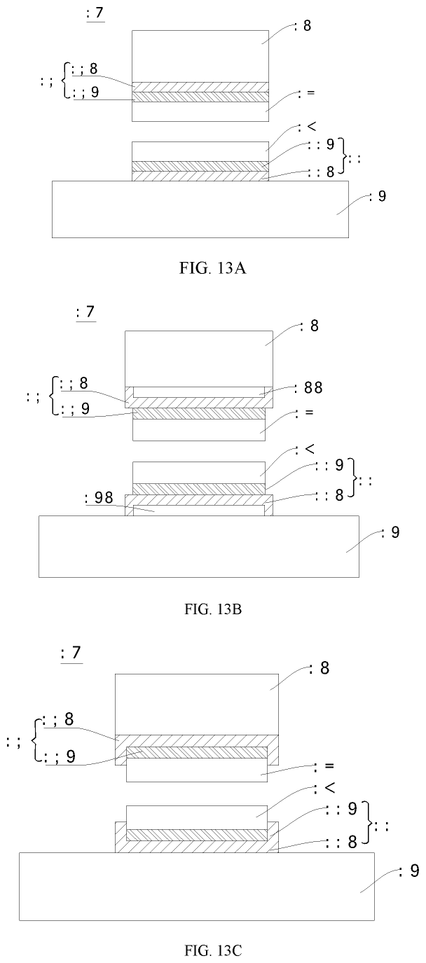

As shown in FIG. 13A, the third embodiment of the disclosure provides a bonding assembly which includes a micro-electronic element 31 and a substrate 32 for bonding the micro-electronic element 31. The substrate 32 is provided with a bonding pad 33. The micro-electronic element 31 is provided with a bonding pad 34 corresponding to the bonding pad 33. The bonding assembly 30 further includes a solder layer 35 and a solder layer 36. The solder layer 35 is disposed between the bonding pad 33 and the bonding pad 34. The solder layer 36 is disposed between the solder layer 35 and the bonding pad 34. A melting point of the solder layer 36 is different from that of the solder layer 35. In an illustrated embodiment, the solder layer 35 and the solder layer 36 are both fixed on one of the bonding pad 33 of the bonding pad 34. In another illustrated embodiment, one of the solder layer 35 and the solder layer 36 is fixed on the bonding pad 33, and the other of the solder layer 35 and the solder layer 36 is fixed on the bonding pad 34. Specifically, there are three types of fixing methods of the solder layer 35 and the solder layer 36. Referring to FIG. 13A, the first type is that the solder layer 35 is fixed on the bonding pad 33 and the solder layer 36 is fixed on the bonding pad 34. The second type is that the solder layer 35 is fixed on the bonding pad 33, and the solder layer 36 is fixed on a side of the solder layer 35 facing away from the bonding pad 33, which means that the solder layer 36 is indirectly fixed on the bonding pad 33. The third type is that the solder layer 36 is fixed on the bonding pad 34, and the solder layer 35 is fixed on a side of the solder layer 36 facing away from the bonding pad 34, which means that the solder layer 35 is indirectly fixed on the bonding pad 34.

In the embodiment, the micro-electronic element 31 is a Micro LED chip, and specially, a flip-chip Micro LED chip, and the substrate 32 is a drive circuit substrate for bonding the Micro LED. The substrate 32 includes a support base and a drive circuit layer disposed on the support base. The bonding pad 33 is disposed on the drive circuit layer and electrically connected to the drive circuit layer, so that when the Micro LED chip is bonded to the substrate 32, the electrical connection between the Micro LED and the drive circuit layer is realized, and the Micro LED is driven to work through the drive circuit layer. It should be noted that FIG. 13A only illustrates there being one bonding pad 33 on the substrate 32, so that in the third embodiment, the substrate 32 is provided with multiple bonding pads 33, in an illustrated embodiment of the disclosure, there are multiple micro-electronic elements 31, and each micro-electronic element 31 has two bonding pads 34 which are respectively connected to the P-type semiconductor layer and the N-type semiconductor layer. The substrate 32 is also provided with two bonding pads 33 at the position corresponding to each the micro-electronic element 31. It should be understood that the number of the solder layer 35 and the number of the solder layer 36 correspond to the number of the bonding pad 33 and the number of the bonding pad 34. In an illustrated embodiment of the disclosure, the bonding pad 33 includes an adhesive layer 331 and a solder pad layer 332, and the adhesive layer 331 is disposed between the solder pad layer 332 and the substrate 32; the bonding pad 34 includes an adhesive layer 341 and a solder pad layer 342, and the adhesive layer 341 is disposed between the solder pad layer 342 and the micro-electronic element 31. The adhesive layer 331 and the adhesive layer 341 can be specifically Cr metal layer or Ti metal layer, etc., and the solder pad layer 332 and the solder pad layer 342 can be specifically Cu metal layer or Ni metal layer, etc. The bonding pad 33 and the bonding pad 34 are used to combine with solder to realize the bonding. In an illustrated embodiment of the disclosure, the solder pad layer 332 and the solder pad layer 342 are mainly used to combine with the solder, the adhesive layer 331 is mainly used to isolate the solder pad layer 332 and the substrate 32, and the adhesive layer 341 is mainly used to isolate the solder pad layer 342 and the micro-electronic element 31. The solder layer 35 and the solder layer 36 are specially made of alloy solder with low melting point. The melting point relationship between the solder layer 35 and the solder layer 36 can be determined according to their position relationship.

In some embodiments, the micro-electronic element 31 further includes a chip electrode 311 on its surface and the bonding pad 34 connects to the chip electrode 311. In some embodiments, an area of orthographic projection P1 of the chip electrode 311 on a surface of the micro-electronic element 31 is different from an area of orthographic projection P4 of the bonding pad 34 on the surface of the micro-electronic element 31, specifically, P4 is greater than P1. In an illustrated embodiment, P4 is 1.15-2.5 times of P1, which effectively isolate the chip electrode 311 from the solder layer 36 and achieve better solder resistance effect. In the illustrated embodiment, an area of orthographic projection P41 of the adhesive layer 341 on the surface of the micro-electronic element 31 is greater than P1, and P41 is 1.15-2.5 times of P1. As shown in FIG. 13B, the adhesive layer 341 also extends to a side of the chip electrode 311 facing toward a side close to the surface of the micro-electronic element 31 to achieve better obstructive effect. An area of orthographic projection P42 of the solder pad layer 342 on the surface of the micro-electronic element 31 can be less than P41.

In some embodiments, the substrate 32 includes a substrate electrode 321 on a surface of the substrate 32 and the bonding pad 33 connects to the substrate electrode 321. In some embodiments, an area of orthographic projection P2 of the substrate electrode 321 on the surface of the substrate 32 is different from an area of orthographic projection P3 of the bonding pad 33 on the surface of the substrate 21, specifically, P3 is greater than P2, and more specifically, P3 is 1.15-2.5 times of P2. In an illustrated embodiment, an area of orthographic projection P31 of the adhesive layer 331 on the surface of the substrate 21 is greater than P2, and P31 is 1.15-2.5 times of P2. As shown in FIG. 13B, the adhesive layer 331 also extends to a side of the substrate electrode 321 facing toward a side close to the surface of the substrate 21 to achieve better obstructive effect. An area of orthographic projection P32 of the solder pad layer 332 on the surface of the substrate 21 can be less than P31.

In some embodiments, an area of orthographic projection of the solder layer 35 on the surface of the micro-electronic element 31 (or an area of orthographic projection on a mounting surface of the substrate 32) P5 is less than P3 and less than P4. In an illustrated embodiment, P3 can be 1.15-2.5 times of P5, and P4 can be 1.15-2.5 times of P5. The illustrated embodiment does not limit a size relationship between P3 and P4. As shown in FIG. 13C, when the solder layer 35 is disposed on the bonding pad 33, the adhesive layer 331 can extend to a side of the solder layer 35 facing toward a side close to the solder layer 35. It can be understood that the adhesive layer 331 forms a groove thereon and the solder layer 35 is disposed in the groove.

In some embodiments, an area of orthographic projection of the solder layer 36 on the surface of the micro-electronic element 31 (or an area of orthographic projection on a mounting surface of the substrate 32) P6 is less than P3 and less than P4. In an illustrated embodiment, P3 can be 1.15-2.5 times of P6, and P4 can be 1.15-2.5 times of P6. The illustrated embodiment does not limit a size relationship between P3 and P4. As shown in FIG. 13C, when the solder layer 36 is disposed on the bonding pad 34, the adhesive layer 341 can extend to a side of the solder layer 36 facing toward a side close to the solder layer 36. It can be understood that the adhesive layer 341 forms a groove thereon and the solder layer 36 is disposed in the groove.

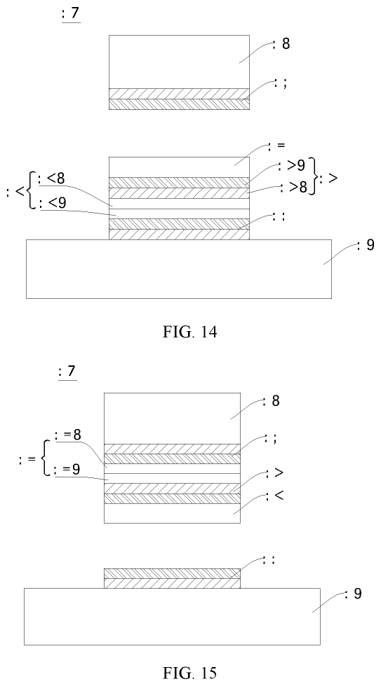

Referring to FIG. 14, in some embodiments, the bonding assembly 30 further includes a bonding pad 37, which is disposed between the solder layer 35 and the solder layer 36. Similar to the bonding pad 33 and the bonding pad 34, the bonding pad 37 includes an adhesive layer 371 and a solder pad layer 372. In an illustrated embodiment of the disclosure, the adhesive layer 371 can be Cr metal layer or Ti metal layer, and the solder pad layer 372 can be Cu metal layer or Ni metal layer. When the solder layer 35 is fixed on the bonding pad 33 and the solder layer 36 is fixed on the bonding pad 34, the bonding pad 37 can be either fixed on the solder layer 35 or fixed on the solder layer 36. When the bonding pad 37 is fixed on the solder layer 35, the adhesive layer 371 is disposed between the solder layer 35 and the solder pad layer 372, and when the bonding pad 37 is fixed on the solder layer 36, the adhesive layer 371 is disposed between the solder layer 36 and the solder pad layer 372. If the solder layer 35 and the solder layer 36 are fixed in the same way (referring to both at the bonding pad 33 or both at the bonding pad 34), the bonding pad 37 is fixed between the solder layer 35 and the solder layer 36. When the bonding pad 37 is fixed on a side of the substrate 32, the adhesive layer 371 is disposed between the solder layer 35 and the solder pad layer 372. When the bonding pad 37 is fixed on a side of the micro-electronic element 31, the adhesive layer 371 is disposed between the solder layer 36 and the solder pad layer 372.

In some embodiments, when the bonding pad 37 is fixed on a side of the substrate 32, an area of orthographic projection P7 of the bonding pad 37 on the surface of the substrate 32 is greater than the area of orthographic projection P6 of the solder layer 36 on the surface of the substrate 32, and P7 can be 1.15-2.5 times of P6. In an illustrated embodiment, an area of orthographic projection P71 of the adhesive layer 371 on the surface of the substrate 32 is greater than P6 and P71 is 1.15-2.5 times of P6.

In some embodiments, when the bonding pad 37 is fixed on a side of the micro-electronic element 31, an area of orthographic projection P7 of the bonding pad 37 on the surface of the micro-electronic element 31 is greater than the area of orthographic projection P5 of the solder layer 35 on the surface of the micro-electronic element 31, and P7 can be 1.15-2.5 times of P5. In an illustrated embodiment, an area of orthographic projection P71 of the adhesive layer 371 on the surface of the micro-electronic element 31 is greater than P5 and P71 can be 1.15-2.5 times of P5.

In some embodiments, the solder layer 35 and the solder layer 36 are both alloy materials, for example, bismuth tin alloy (melting point of 145° C.) and silver tin alloy (melting point of 221° C.). The melting points of the two solder layers are different. The welding temperature can be controlled to make only one of them melt. When the solder layer 35 is fixed on the bonding pad 33 and the bonding pad 37 is fixed on the solder layer 35 (at this time, the solder layer 36 is fixed on the bonding pad 37 or on the bonding pad 34), the melting point of the solder layer 35 is higher than that of the solder layer 36. When the solder layer 36 is fixed on the bonding pad 34 and the bonding pad 37 is fixed on the solder layer 36 (at this time, the solder layer 35 is fixed on the bonding pad 37 or on the bonding pad 33), the melting point of the solder layer 35 is lower than that of the solder layer 36.

In other embodiments, when the solder layer 35 is fixed on the bonding pad 33 and the bonding pad 37 is fixed on the solder layer 35 (at this time, the solder layer 36 can be fixed on the bonding pad 37 or on the bonding pad 34), the solder layer 35 can adopt a stacked structure of pure metal layers, and in an illustrated embodiment of the disclosure, the solder layer 36 adopts alloy solder. Referring to FIG. 14, the solder layer 35, the bonding pad 37 and the solder layer 36 are fixed on the side of the substrate 32. The solder layer 35 includes a metal layer 351 and a metal layer 352, the metal layer 351 and the metal layer 352 are capable of alloying to form an alloy layer. A melting point of each of the metal layer 351 and the mental layer 352 is higher than that of the solder layer 36 and a melting point of the alloy layer after alloying the metal layer 351 and the mental layer 352 is lower than that of the solder layer 36.

In other embodiments, when the solder layer 36 is fixed on the bonding pad 34 and the bonding pad 37 is fixed on the solder layer 36 (at this time, the solder layer 35 is fixed on the bonding pad 37 or on the bonding pad 33), the solder layer 36 can adopt a stacked structure of pure metal layers, and the solder layer 35 adopts alloy solder. Referring to FIG. 15, the solder layer 35, the bonding pad 37 and the solder layer 36 are fixed on the side of the micro-electronic element 31. In an illustrated embodiment of the disclosure, the solder layer 36 includes a metal layer 361 and a metal layer 362, the metal layer 361 and the metal layer 362 are capable of alloying to form an alloy layer. A melting point of each of the metal layer 361 and the metal layer 362 is higher than that of the solder layer 35, and a melting point of the alloy layer after alloying the metal layer 361 and the mental layer 362 is lower than that of the solder layer 35.

The bonding assembly 30 provided in the third embodiment of the disclosure forms a structure of two-layer solder layer between the micro-electronic element 31 and the substrate 32. The melting points of the two solder layers are different from each other, and the two solder layers are used for two bonding welding processes at the same bonding position. The specific principle and process of the bonding assembly 30 to realize the two bonding processes can respectively refer to the descriptions described in the above first and second embodiments of the disclosure, which are not described again herein.

The above description is only the illustrated embodiments of the disclosure and does not limit the disclosure in any form. Although the disclosure has been disclosed in the above embodiments, it is not intended to limit the disclosure. Any person skilled in the art can make some amendments or modifications as equivalent embodiments according to the above disclosed technical contents without departing from the technical scope of the disclosure. If those skilled cannot depart from the technical scope of the disclosure, any simple amendments, equivalent changes and modifications to the above embodiments according to the technical essence of the disclosure are still within the technical scope of the disclosure.

What is claimed is:

1. A micro-electronic component, comprising:
a micro-electronic element;
a first bonding pad, disposed on a side of the micro-electronic element;
a first solder layer, disposed on a side of the first bonding pad facing away from the micro-electronic element; and
a second bonding pad, disposed on a side of the first solder layer facing away from the first bonding pad.

2. The micro-electronic component according to claim 1, wherein the micro-electronic component further comprises: a second solder layer disposed on a side of the second bonding pad facing away from the first solder layer.

3. The micro-electronic component according to claim 2, wherein a melting point of the second solder layer is lower than that of the first solder layer.

4. The micro-electronic component according to claim 2, wherein the first solder layer comprises: a first metal layer and a second metal layer; the first metal layer and the second metal layer are capable of alloying to form a first alloy layer; a melting point of each of the first metal layer and the second metal layer is greater than a melting point of the second solder layer; and a melting point of the first alloy layer is lower than that of the second solder layer.

5. The micro-electronic component according to claim 1, wherein the first bonding pad comprises: a first adhesive layer and a first solder pad layer; the first adhesive layer is disposed between the first solder pad layer and the micro-electronic element; the second bonding pad comprises: a second adhesive layer and a second solder pad layer; and the second adhesive layer is disposed between the first solder layer and the second solder pad layer.

6. The micro-electronic component according to claim 1, wherein the micro-electronic element comprises a chip electrode on a surface of the micro-electronic element, the first bonding pad connects to the chip electrode, and an area of orthographic projection of the first bonding pad on the surface of the micro-electronic element is 1.15-2.5 times of an area of orthographic projection of the chip electrode on the surface of the micro-electronic element.

7. The micro-electronic component according to claim 1, wherein an area of orthographic projection of the first bonding pad on a surface of the micro-electronic element is 1.15-2.5 times of an area of orthographic projection of the first solder layer on the surface of the micro-electronic element.

8. A bonding backplate, comprising:
a substrate;
a first bonding pad, disposed on a side of the substrate;
a first solder layer, disposed on a side of the first bonding pad facing away from the substrate;
a second bonding pad, disposed on a side of the first solder layer facing away from the first bonding pad.

9. The bonding backplate according to claim 8, wherein the first solder layer comprises: a first metal layer and a second metal layer; the first metal layer and the second metal layer are capable of alloying to form a first alloy layer.

10. The bonding backplate according to claim 8, wherein the bonding backplate further comprises: a second solder layer disposed on a side of the second bonding pad facing away from the first solder layer.

11. The bonding backplate according to claim 8, wherein the substrate comprises a substrate electrode on a surface of the substrate and an area of orthographic projection of the first bonding pad on the surface of the substrate is 1.15-2.5 times of an area of orthographic projection of the substrate electrode on the surface of the substrate.

12. The bonding backplate according to claim 8, wherein an area of orthographic projection of the first bonding pad on a surface of the substrate is 1.15-2.5 times of an area of orthographic projection of the first solder layer on the surface of the substrate.

13. A bonding assembly, comprising:
a micro-electronic element;
a substrate, configured to bond the micro-electronic element;
a first bonding pad, disposed on the substrate;
a second bonding pad corresponding to the first bonding pad, disposed on the micro-electronic element;
wherein the bonding assembly further comprises:
a first solder layer, disposed between the first bonding pad and the second bonding pad;
a second solder layer, disposed between the first solder layer and the second bonding pad, and a melting point of the second solder layer is different from that of the first solder layer; and
wherein the first solder layer and the second solder layer are fixed on one of the first bonding pad and the second bonding pad; or
one of the first solder layer and the second solder layer is fixed on the first bonding pad, and the other is fixed on the second bonding pad.

14. The bonding assembly according to claim 13, wherein the first solder layer and the second solder layer are fixed on the first bonding pad and the melting point of the first solder layer is higher than that of the second solder layer.

15. The bonding assembly according to claim 13, the first solder layer and the second solder layer are fixed on the second bonding pad, and the melting point of the second solder layer is higher than that of the first solder layer.

16. The bonding assembly according to claim 13, wherein the bonding assembly further comprises: a third bonding pad, disposed between the first solder layer and the second solder layer.

17. The bonding assembly according to claim 16, wherein the first solder layer is fixed on the first bonding pad, the third bonding pad is fixed on the first solder layer, and the melting point of the first solder layer is higher than that of the second solder layer.

18. The bonding assembly according to claim 16, wherein the second solder layer is fixed on the second bonding pad, the third bonding pad is fixed on the second solder layer, and the melting point of the second solder layer is higher than that of the first solder layer.

19. The bonding assembly according to claim 16, wherein the first solder layer is fixed on the first bonding pad and the third bonding pad is fixed on the first solder layer, the first solder layer comprises: a first metal layer and a second metal layer, and the first metal layer and the second metal layer are capable of alloying to form a first alloy layer; or
wherein the second solder layer is fixed on the second bonding pad and the third bonding pad is fixed on the second solder layer, the second solder layer comprises: a third metal layer and a fourth metal layer, and the third metal layer and the fourth metal layer are capable of alloying to form a second alloy layer.

20. The bonding assembly according to claim 13, wherein the substrate comprises a substrate electrode on a surface of the substrate, the first bonding pad connects to the substrate electrode, and an area of orthographic projection of the first bonding pad on the surface of the substrate is 1.15-2.5 times of an area of orthographic projection of the substrate electrode on the surface of the substrate; and/or
wherein the micro-electronic element comprises a chip electrode on a surface of the micro-electronic element, the second bonding pad connects to the chip electrode, and an area of orthographic projection of the second bonding pad on the surface of the micro-electronic element is 1.15-2.5 times of an area of orthographic projection of the chip electrode on the surface of the micro-electronic element.
